(19) United States
(12) Patent Application Publication
(10) Pub. No.: US 2026/0180563 A1
(43) Pub. Date: Jun. 25, 2026

(54) SEMICONDUCTOR DEVICE

(71) Applicant: Renesas Electronics Corporation, Tokyo (JP)

(72) Inventor: Atsushi MOTOZAWA, Tokyo (JP)

(21) Appl. No.: 19/394,123

(22) Filed: Nov. 19, 2025

(30) Foreign Application Priority Data
Dec. 24, 2024 (JP) 2024-227849

(51) Int. Cl. H03K 4/06; H03K 3/037; H03K 17/687

(52) U.S. Cl. CPC H03K 4/06; H03K 3/037; H03K 17/6872

(57) ABSTRACT

A semiconductor device includes a reference current generation circuit, a replica current generation circuit, a first ramp wave signal generation circuit and a second ramp wave signal generation circuit, and a correction circuit. The reference current generation circuit includes a first MOSFET and a first resistor, and is configured such that a reference current flows through the first MOSFET and the first resistor. The replica current generation circuit includes a second MOSFET through which a replica current of M times the reference current flows. A first ramp wave signal generation circuit and a second ramp wave signal generation circuit alternately generate ramp wave signals. A correction circuit that generates a voltage according to a current value of the reference current, and generates the first potential as a potential, which is shifted to a positive side, from the gate potential of the first MOSFET by the generated voltage.

### CROSS-REFERENCE TO RELATED APPLICATIONS

The disclosure of Japanese Patent Application No. 2024-227849 filed on Dec. 24, 2024 including the specification, drawings and abstract is incorporated herein by reference in its entirety.

### BACKGROUND

The present invention relates to a semiconductor device, and is suitably applicable to, for example, a semiconductor device including an oscillation circuit.

There are disclosed techniques listed below.
[Patent Document 1] Japanese Unexamined Patent Application Publication No. 2019-9345.

A semiconductor device including an oscillation circuit is known. A semiconductor device including such an oscillation circuit is described in, for example, Patent Document 1.

### SUMMARY

The oscillation circuit has a temperature characteristic, and an oscillation frequency thereof varies depending on an ambient temperature. That is, improving precision of the oscillation frequency of the oscillation circuit included in the semiconductor device is one of problems to be addressed.

Other problems and novel features will become apparent from the description of the present specification and the accompanying drawings.

According to one embodiment, a semiconductor device includes an oscillation circuit. The oscillation circuit includes a reference current generation circuit, a replica current generation circuit, a first ramp wave signal generation circuit and a second ramp wave signal generation circuit, and a correction circuit. The reference current generation circuit includes a first MO transistor and a first resistor having a resistance temperature coefficient, and is configured such that a reference current flows through the first MOS transistor and the first resistor. The replica current generation circuit includes a second MOS transistor through which a replica current of M times the reference current flows by application of a first potential, which is based on a gate potential of the first MOS transistor, to a gate of the second MOS transistor. A first ramp wave signal generation circuit and a second ramp wave signal generation circuit alternately generate ramp wave signals based on charging and discharging of the replica current. A correction circuit that generates a voltage according to a current value of the reference current, and generates the first potential as a potential, which is shifted to a positive side, from the gate potential of the first MOS transistor by the generated voltage.

According to the embodiment, in the semiconductor device including the oscillation circuit, precision of the oscillation frequency can be improved.

### BRIEF DESCRIPTION OF THE DRAWINGS

FIG. 1 is a block diagram illustrating a configuration of a semiconductor device.

FIG. 2 is a circuit diagram of a reference oscillation circuit.

FIG. 3 is a diagram illustrating waveforms of an output node voltage of a switch circuit and an output voltage of a latch circuit.

FIG. 4 is a graph illustrating a temperature characteristic of an oscillation frequency in the oscillation circuit.

FIG. 5 is a circuit diagram illustrating an example of the oscillation circuit in the semiconductor device according to the embodiment.

FIG. 6 is a graph illustrating temperature characteristics of gate-to-source voltages of transistors.

FIG. 7 is a circuit diagram illustrating an example of the oscillation circuit in the semiconductor device according to the embodiment.

FIG. 8 is a graph illustrating a relationship among a resistance ratio, precision of an oscillation frequency, and a temperature range.

FIG. 9 is a circuit diagram of a reference current generation circuit illustrated in FIG. 7.

FIG. 10 is a diagram illustrating a first pattern layout example of the reference current generation circuit on a semiconductor substrate.

FIG. 11 is a diagram illustrating a second pattern layout example of the reference current generation circuit on the semiconductor substrate.

FIG. 12 is a circuit diagram of the reference current generation circuit in the semiconductor device according to the embodiment.

FIG. 13 is a diagram illustrating a third pattern layout example of the reference current generation circuit on the semiconductor substrate.

### DETAILED DESCRIPTION

Hereinafter, an embodiment will be described. First, a configuration of a reference semiconductor device will be described. Next, a process of examination by the present inventor will be described. Thereafter, the embodiment of the semiconductor device proposed by the present inventor will be described.

In the present specification, identical or corresponding components in the embodiment are denoted by the same reference numerals, and repeated description thereof is omitted except when necessary.

### (Reference Semiconductor Device and Oscillation Circuit Thereof)

### <Reference Semiconductor Device>

FIG. 1 is a block diagram illustrating a configuration of a semiconductor device 1. As illustrated in FIG. 1, on a substrate of the semiconductor device 1, active elements such as transistors and passive elements such as resistors and capacitors are formed. In the semiconductor device 1, various functional blocks are formed by using these elements. FIG. 1 illustrates, as examples of the functional blocks, a Central Processing Unit (CPU) 2, a RAM 3, a peripheral IP 4, and a nonvolatile memory 5. The peripheral IP is a signal processing device, such as an A/D converter. Between these functional blocks, information such as addresses and data is exchanged via a bus 10. A clock generation circuit 7 generates a clock from an oscillation signal of an oscillation circuit 8 and distributes the clock to these functional blocks.

### <Reference Oscillation Circuit>

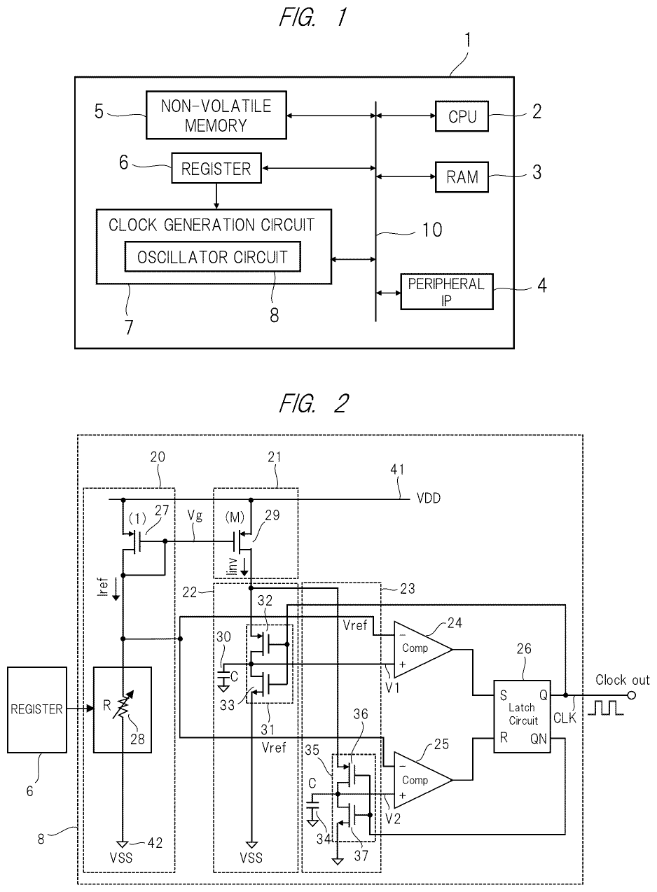

FIG. 2 is a circuit diagram of a reference oscillation circuit 8. The oscillation circuit 8 is, for example, an on-chip oscillator. The oscillation circuit 8 includes a reference current generation circuit 20, a replica current generation circuit 21, a first ramp wave signal generation circuit 22, a second ramp wave signal generation circuit 23, two comparators 24 and 25, and a latch circuit 26. Here, the latch circuit 26 is assumed to be an SR latch circuit.

The reference current generation circuit 20 includes a first P-type MOS transistor 27 and a first resistor 28, and is configured such that a reference current Iref flows through the first P-type MOS transistor 27 and the first resistor 28. The first resistor 28 has a resistance temperature coefficient. The resistance temperature coefficient of the first resistor 28 may be either positive or negative. Here, the resistance temperature coefficient of the first resistor 28 is assumed to be a positive value or a function that derives a positive value. The first P-type MOS transistor 27 corresponds to a “first MOS transistor” in the present application.

In the reference current generation circuit 20, a source of the first P-type MOS transistor 27 is connected to a high-potential power supply line VDD. A drain of the first P-type MOS transistor 27 is connected to one end of the first resistor 28. The other end of the first resistor 28 is connected to a low-potential power supply line VSS. The low-potential power supply line VSS is, for example, a line connected to a ground terminal. A gate of the first P-type MOS transistor 27 is connected to the drain thereof. Through a source-drain path of the first P-type MOS transistor 27 and the first resistor 28, the reference current Iref corresponding to a resistance value of the first resistor 28 flows.

The replica current generation circuit 21 includes a second P-type MOS transistor 29. A transistor size of the second P-type MOS transistor 29 is M times a transistor size of the first P-type MOS transistor 27. A gate potential Vg of the first P-type MOS transistor 27 is applied to a gate of the second P-type MOS transistor 29. Through a source-drain path of the second P-type MOS transistor 29, a replica current Iinv having a current value of M times a current value of the reference current Iref flows. The second P-type MOS transistor 29 corresponds to a “second MOS transistor” in the present application.

Further, the first ramp wave signal generation circuit 22 and the second ramp wave signal generation circuit 23 are configured to alternately generate ramp wave signals based on charging and discharging of the replica current Iinv.

Here, the first ramp wave signal generation circuit 22 includes a capacitor 30 and a switch circuit 31. Also, the switch circuit 31 includes a switch P-type MOS transistor 32 and a switch N-type MOS transistor 33. In the switch circuit 31, a drain of the switch P-type MOS transistor 32 and a drain of the switch N-type MOS transistor 33 are connected to each other.

A drain of the second P-type MOS transistor 29 is connected to a source of the switch P-type MOS transistor 32. A source of the switch N-type MOS transistor 33 is connected to a low-potential power supply line VSS. The capacitor 30 is connected between a drain and a source of the switch N-type MOS transistor 33. A gate of the switch P-type MOS transistor 32 is connected to a gate of the switch N-type MOS transistor 33.

That is, the switch circuit 31 includes the switch P-type MOS transistor 32 and the switch N-type MOS transistor 33, whose source-drain paths are connected in series. The source of the switch N-type MOS transistor 33 is connected to the low-potential power supply line VSS, and the drain of the switch N-type MOS transistor 33 is connected to the drain of the switch P-type MOS transistor 32. A connection point between the drain of the switch P-type MOS transistor 32 and the drain of the switch N-type MOS transistor 33 is an output node of the switch circuit 31, and the capacitor 30 is connected to this output node. To the source of the switch P-type MOS transistor 32, the replica current Iinv having a current value of M times a current value of the reference current Iref is input.

The gate of the switch P-type MOS transistor 32 and the gate of the switch N-type MOS transistor 33 that are commonly connected, are connected to an output terminal of the latch circuit 26, and receive an output signal Q. The capacitor 30 is connected between the output node of the switch circuit 31 and the low-potential power supply line VSS, so that a voltage corresponding to an amount of charge accumulated in the capacitor 30 is generated at the output node of the switch circuit 31.

With such a configuration, charging and discharging of the capacitor 30 by the replica current Iinv is performed by switching of the switch circuit 31. In the switch circuit 31, when the switch P-type MOS transistor 32 is turned on and the switch N-type MOS transistor 33 is turned off, a switch is turned on. At this point, the capacitor 30 is charged with a charge of the replica current Iinv. On the other hand, when the switch P-type MOS transistor 32 is turned off and the switch N-type MOS transistor 33 is turned on, the switch is turned off. At this point, the charge of the replica current Iinv accumulated in the capacitor 30 is discharged.

The second ramp wave signal generation circuit 23 has substantially the same configuration as the first ramp wave signal generation circuit 22 and performs substantially the same operation. However, generation timing of a ramp wave signal has a phase different by 180 degrees as compared with the first ramp wave signal generation circuit 22. The second ramp wave signal generation circuit 23 includes a capacitor 34 and a switch circuit 35. The switch circuit 35 includes a switch P-type MOS transistor 36 and a switch N-type MOS transistor 37. In the switch circuit 35, a drain of the switch P-type MOS transistor 36 and a drain of the switch N-type MOS transistor 37 are connected to each other.

A source of the switch P-type MOS transistor 36 is connected to the drain of the second P-type MOS transistor 29. A source of the switch N-type MOS transistor 37 is connected to a low-potential power supply line VSS. The capacitor 34 is connected between a drain and a source of the switch N-type MOS transistor 37. A gate of the switch P-type MOS transistor 36 is connected to a gate of the switch N-type MOS transistor 37.

As described above, the replica current Iinv flows through the source-drain path of the second P-type MOS transistor 29. That is, the replica current Iinv is input to the source of the switch P-type MOS transistor 36. The gate of the switch P-type MOS transistor 36 and the gate of the switch N-type MOS transistor 37 that are commonly connected, are connected to the output terminal of the latch circuit 26, and receive an output signal QN. The capacitor 34 is connected between an output node of the switch circuit 35 and the low-potential power supply line VSS, so that a voltage corresponding to an amount of charge accumulated in the capacitor 34 is generated at the output node of the switch circuit 35.

To an inverting input terminal (−) of the comparator 24, a reference voltage Vref is input, and to a non-inverting input terminal (+) thereof, an output node voltage V1 of the switch circuit 31 is input. The comparator 24 switches a logic level of a set signal S according to a magnitude relationship between the reference voltage Vref and the output node voltage V1. Specifically, when the output node voltage V1 is greater than the reference voltage Vref, the comparator 24 sets the set signal S to a high level. When the output node voltage V1 is smaller than the reference voltage Vref, the comparator 24 sets the set signal S to a low level. The comparator 25, which switches a logic level of a reset signal R, performs the same operation as the comparator 24. Although detailed description is omitted, a reference voltage Vref is input to an inverting input terminal (−) of the comparator 25, and an output node voltage V2 of the switch circuit 35 is input to a non-inverting input terminal (+) thereof. The reference voltage Vref corresponds to a “reference potential” in the present application.

It is preferable that the comparator 24 (25) be a hysteresis comparator in order to stably switch a logic level of the set signal S (reset signal R) to be output. The hysteresis comparator switches the set signal S (reset signal R) from a low level to a high level when the output node voltage V1 (V2)>the reference voltage Vref, assuming that a hysteresis width is dh. Further, the hysteresis comparator switches the set signal S (reset signal R) from a high level to a low level when the output node voltage V1 (V2)+dh<the reference voltage Vref.

A resistance value R of the first resistor 28 is adjusted to a predetermined value, and an oscillation frequency f of the oscillation circuit 8 is set to a desired value for each semiconductor device 1. The first resistor 28 is adjusted by a so-called trimming circuit. A trimming code necessary for trimming is written into the nonvolatile memory 5 or the RAM 3. The resistance value R of the first resistor 28 is adjusted to the predetermined value based on the trimming code read via a register 6. Further, a current value Iref of the reference current Iref flowing through the source-drain path of the first P-type MOS transistor 27 is adjusted according to the resistance value R of the first resistor 28. Thus, a frequency of a clock to be output is adjusted.

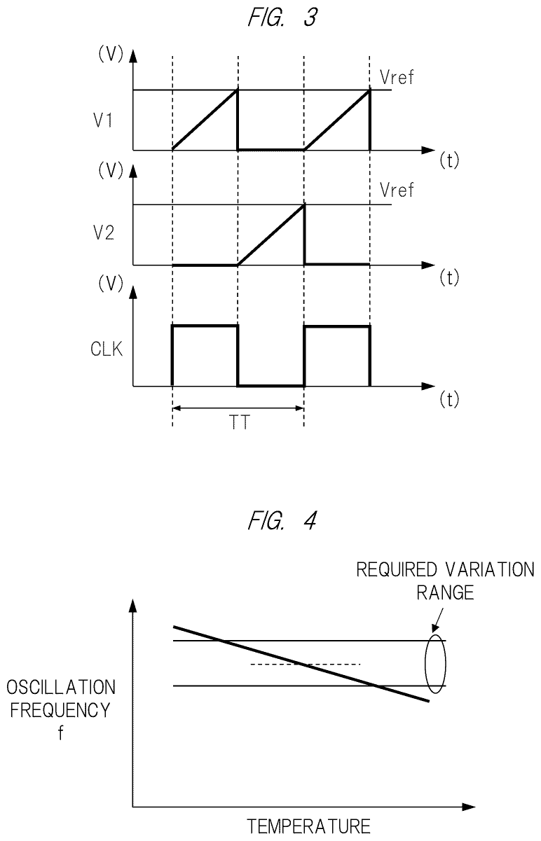

FIG. 3 is a diagram illustrating waveforms of an output node voltage of the switch circuit and an output voltage of the latch circuit. In each graph illustrated in FIG. 3, a horizontal axis represents time, and a vertical axis represents a voltage value. As illustrated in FIG. 3, ramp wave signals alternately appear in the output node voltage V1 of the switch circuit 31 and the output node voltage V2 of the switch circuit 35. At timing when either one of the output node voltages V1 and V2 exceeds the reference voltage Vref, a level of a set signal S or a reset signal R of the latch circuit 26 is switched. Accordingly, a level of an output signal Q of the latch circuit 26 is periodically switched, and a rectangular wave signal CLK having a period TT is generated.

Here, description will be made regarding the oscillation frequency f of the oscillation circuit 8. The oscillation frequency f is obtained by the following Expression (1). T represents a period which is a reciprocal of the oscillation frequency f.

$$\begin{matrix}[ Expression 1 ] & \\ {V}_{ref} = R {I}_{ref} & ( 1 )\end{matrix}$$

$$T = \frac{2 {V}_{r e f} C}{{I}_{ref}} = 2 R C ( \frac{{I}_{ref}}{{I}_{inv}} )$$

$${I}_{inv} = {MI}_{ref}$$

$$T = 2 RC \cdot \frac{1}{M}$$

$$∴ f = \frac{M}{2 R C}$$

Thus, the oscillation frequency f is determined by a resistance value R of the first resistor 28, a capacitance C of the capacitors 30 and 34, and a ratio M.

As understood from the above, the oscillation circuit 8 is relatively easy to adjust the oscillation frequency f and does not require a complicated circuit. Therefore, the oscillation circuit 8 is often mounted, for example, in products for in-vehicle use as an internal oscillation circuit of an IC.

On the other hand, an operating temperature range of the oscillation circuit required for in-vehicle use is wider than that for consumer use. Further, in the oscillation circuit for in-vehicle use, high precision of the oscillation frequency has been required in recent years. For example, assuming that the operating temperature range is from −40° C. to 170° C., a required precision of the oscillation frequency f is ±5%, as compared with a conventional ±10%.

### (Process of Examination by Present Inventor)

### <Temperature Characteristic of Oscillation Frequency in Oscillation Circuit>

Generally, a resistor has a resistance temperature coefficient, and a resistance value thereof varies with temperature. Therefore, as understood from the above Expression, the oscillation frequency f is affected by a temperature characteristic of the first resistor 28 and varies with temperature.

FIG. 4 is a graph illustrating a temperature characteristic of the oscillation frequency in the oscillation circuit. In a graph illustrated in FIG. 4, a horizontal axis represents temperature, and a vertical axis represents the oscillation frequency. It is assumed that the first resistor 28 has, for example, a positive resistance temperature coefficient. That is, it is assumed that a resistance value R of the first resistor 28 varies with a positive slope with respect to temperature. In this case, assuming that temperature characteristics of the ratio M and the capacitance C are negligible, the oscillation frequency f varies with a negative slope with respect to temperature, as illustrated in FIG. 4. Hereinafter, such a temperature characteristic is also referred to as a negative temperature characteristic.

<Problems with Reference Oscillation Circuit>

According to the examination by the present inventor, when the oscillation circuit having the negative temperature characteristic as described above is used, a problem has been found in that it is difficult to achieve recent required precision which has become more stringent. That is, as illustrated in FIG. 4, a variation range of the oscillation frequency f with respect to a usage temperature range of the oscillation circuit does not fall within a required variation range derived from the required precision.

In order to achieve recent required precision of the oscillation frequency f, it is conceivable to, for example, increase trimming locations and trimming times of the first resistor 28 from the current state, or to use a BGR circuit. However, either method is difficult to adopt because it leads to an increase in test man-hours and cost, an increase in circuit complexity, and an increase in occupied area. Further, when a so-called current mirror circuit is used in the oscillation circuit as in the oscillation circuit 8 illustrated in FIG. 2, it is difficult to control the negative temperature characteristic of the oscillation frequency f.

The present inventor, as a result of intensive examination of the above issue in the oscillation circuit, has obtained an important finding and conceived a semiconductor device proposed in the present application. Hereinafter, the embodiment of the semiconductor device proposed in the present application will be described together with the finding.

### EMBODIMENT

First, the reference current Iref is a function of a resistance value R and has a negative temperature characteristic. In the reference oscillation circuit 8 illustrated in FIG. 2, the first P-type MOS transistor 27 and the second P-type MOS transistor 29 constitute a current mirror circuit. A current value of a replica current Iinv flowing through the second P-type MOS transistor 29 is M times a current value of the reference current Iref. That is, the replica current Iinv has a negative temperature characteristic having a negative slope with respect to temperature.

Here, the present inventor has found that a temperature characteristic of the replica current Iinv, that is, a slope of the current with respect to temperature, can be made smaller, thereby making a temperature characteristic of the oscillation frequency f, that is, a slope of the frequency with respect to temperature, smaller. The present inventor has also found that it is not necessary that the first P-type MOS transistor 27 and the second P-type MOS transistor 29 constitute a current mirror circuit.

Then, the present inventor has reached the following idea. It is sufficient that a temperature coefficient of an absolute value |VGS| of a gate-to-source voltage of the second P-type MOS transistor 29 be smaller than a temperature coefficient of an absolute value |VGS| of a gate-to-source voltage of the first P-type MOS transistor 27. Therefore, a temperature characteristic having a negative slope in the reference current Iref can be utilized. Further, it is sufficient to generate a gate potential of the second P-type MOS transistor 29 by an offset voltage from a gate potential of the first P-type MOS transistor 27, the offset voltage depending on the reference current Iref.

### <Configuration of Oscillation Circuit According to Embodiment>

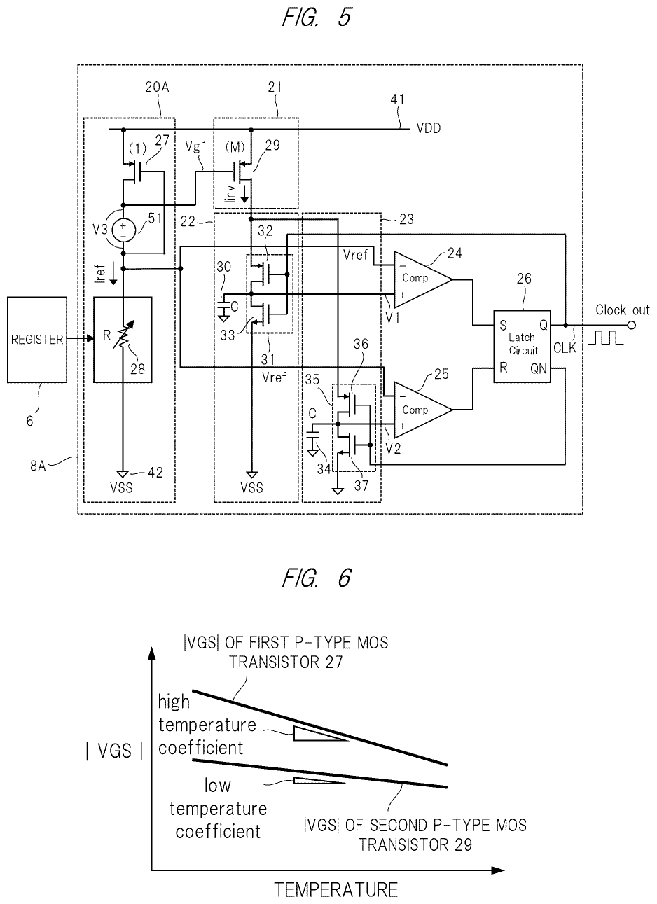

FIG. 5 is a circuit diagram illustrating an example of the oscillation circuit in the semiconductor device according to the embodiment. An oscillation circuit 8A illustrated in FIG. 5 is substantially the same as the oscillation circuit 8 illustrated in FIG. 2 in terms of basic configuration, but is different in the following points.

As illustrated in FIG. 5, in the proposed oscillation circuit 8A, a correction circuit 51 is added, and a connection destination of the gate of the second P-type MOS transistor 29 is different. The correction circuit 51 generates a voltage corresponding to a current value of the reference current Iref. The oscillation circuit 8A is configured such that a first potential Vg1, which is shifted to a positive side by the generated voltage from a gate potential of the first P-type MOS transistor 27, is input to the gate of the second P-type MOS transistor 29. As a specific example, the correction circuit 51 is inserted between a drain of the first P-type MOS transistor 27 and one end of the first resistor 28 and is connected in series with them. A connection point between the drain of the first P-type MOS transistor 27 and the correction circuit 51 is connected to the gate of the second P-type MOS transistor 29.

With such a configuration, a voltage V3 generated by the correction circuit 51 reduces an absolute value |VDS| of a drain-to-source voltage of the first P-type MOS transistor 27. Further, as long as the first P-type MOS transistor 27 is not biased in a linear region, a dependency of the reference current Iref on a voltage value of the voltage V3 is small. As a result, the temperature characteristics of gate-to-source voltages |VGS| of the transistors become as follows.

FIG. 6 is a graph illustrating temperature characteristics of gate-to-source voltages |VGS| of the transistors. In a graph illustrated in FIG. 6, a horizontal axis represents temperature, and a vertical axis represents the gate-to-source voltage |VGS|. As illustrated in FIG. 6, at a low temperature, a potential difference between the gate-to-source voltage |VGS| of the first P-type MOS transistor 27 and the gate-to-source voltage |VGS| of the second P-type MOS transistor 29 is large. On the other hand, at a high temperature, the potential difference between the gate-to-source voltage |VGS| of the first P-type MOS transistor 27 and the gate-to-source voltage |VGS| of the second P-type MOS transistor 29 becomes small. That is, a temperature coefficient of the gate-to-source voltage |VGS| of the second P-type MOS transistor 29 becomes smaller than a temperature coefficient of the gate-to-source voltage |VGS| of t the first P-type MOS transistor 27.

### <Circuit Diagram Illustrating Specific Example of Oscillation Circuit According to Present Embodiment>

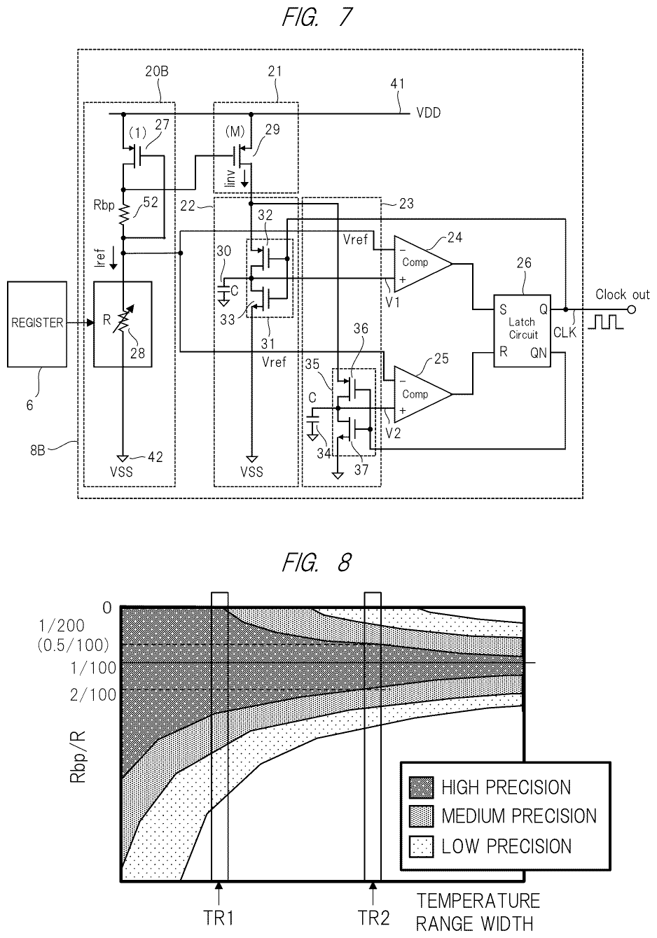

FIG. 7 is a circuit diagram illustrating an example of the oscillation circuit in the semiconductor device according to the embodiment. The oscillation circuit 8B illustrated in FIG. 7 illustrates an example in which a second resistor 52 is used as a specific example of the correction circuit 51 in the oscillation circuit 8A illustrated in FIG. 5. The second resistor 52 has a resistance value Rbp. Here, the second resistor 52 is assumed to have a positive resistance temperature coefficient. A ratio Rbp/R of the resistance value Rbp of the second resistor 52 to the resistance value R of the first resistor 28 is relatively small.

### <Relationship Among Precision of Oscillation Frequency and Temperature Range>

FIG. 8 is a graph illustrating a relationship among a resistance ratio Rbp/R, precision of an oscillation frequency, and a temperature range. In the graph illustrated in FIG. 8, a horizontal axis represents a width of the temperature range, and a vertical axis represents the resistance ratio Rbp/R. Further, in the graph illustrated in FIG. 8, levels of precision of the oscillation frequency are represented by shades of regions. A region having high precision is the darkest region, a region having medium precision is the next darkest region, and a region having low precision is the lightest region. A temperature range TR1 is a relatively narrow temperature range, for example, a range from −20° C. to 70° C. A temperature range TR2 is a relatively wide temperature range, for example, a range from −40° C. to 170° C.

In the temperature range TR1, under a condition in which the resistance ratio Rbp/R is within a range from 0 to a predetermined value equal to or greater than 2/100, high precision of the oscillation frequency can be maintained. The resistance ratio Rbp/R being 0 is equal to the resistance value Rbp being 0 and is equal to a case where the second resistor 52 is not present. That is, in this case, the oscillation circuit 8B becomes the same circuit as the reference oscillation circuit 8 illustrated in FIG. 2. This means that, if a usage temperature range is the temperature range TR1, high precision of the oscillation frequency can be maintained even in the reference oscillation circuit 8.

On the other hand, in the temperature range TR2, under a condition in which the resistance ratio Rbp/R is within a range from 1/200 to 2/100, high precision of the oscillation frequency f can be maintained. When the resistance ratio Rbp/R is 0, that is, in the oscillation circuit 8 in which the second resistor 52 is not present, precision of the oscillation frequency f becomes low. It can be understood that, by setting a resistance value Rbp of the second resistor 52 such that the resistance ratio Rbp/R falls within an appropriate range from 1/200 to 2/100, high precision of the oscillation frequency f can be maintained. Particularly, when the resistance ratio Rbp/R is around 1/100, the precision becomes the highest. For example, when a resistance value R of the first resistor 28 is 10 MΩ, the resistance value Rbp of the second resistor 52 is preferably about 100 kΩ. For example, when the resistance value R of the first resistor 28 is 100 MΩ, the resistance value Rbp of the second resistor 52 is preferably about 1 MΩ. The oscillation frequency f is, for example, assumed to be about several tens of kHz.

### <Consideration of Precision of Oscillation Frequency>

Here, consideration will be made regarding precision of the oscillation frequency in the oscillation circuit 8B according to the present embodiment.

Regarding the resistance ratio, α is defined as α=Rbp/R. A current amplification factor (strength) β1 of the first P-type MOS transistor 27 on a semiconductor substrate can be expressed as β1=Cox×u×W/L. In the expression, Cox is a capacitance of an oxide film per unit area. u is an electron mobility in the semiconductor. W is a gate width (channel width). L is a gate length (channel length). Here, a λ effect is neglected. Then, a gate-to-source voltage Vgsr of the first P-type MOS transistor 27 can be expressed by the following Expression (2).

$$\begin{matrix}[ Expression 2 ] & \\ α = Rbp / R & ( 2 )\end{matrix}$$

$${β}_{1} = Cox * u * W / L$$

$$Rbp = α * R$$

$$V gsr = \sqrt{\frac{2 I r e f}{β 1}} + Vth \approx Vth$$

In Expression (2), Iref is a current value of the reference current Iref, and Vth is a threshold voltage of the transistor. Here, since the Iref is a relatively small value, an overdrive voltage Vov satisfies Vov<Vth (for example, Vov<0.08 [V], Vth≈0.7 [V]).

Further, the current value Iref of the reference current Iref can be expressed by the following Expression (3).

$$\begin{matrix}[ Expression 3 ] & \\ Iref = \frac{Vg}{R} = \frac{V C C - V t h}{R} & ( 3 )\end{matrix}$$

In Expression (3), Vg is a gate potential, and VCC is a voltage value of the power supply, that is, a difference between the high potential VDD and the low potential VSS. Regarding a numerator of Expression (3), when the gate potential at a temperature T0 is Vg0, a gate potential Vg at a temperature T can be expressed by the following Expression (4).

$$\begin{matrix}[ Expression 4 ] & \\ V g = {Vg}_{0} ( 1 + ( {T}_{0} - T ) {K}_{vg} ) & ( 4 )\end{matrix}$$

In Expression (4), Kvg is a temperature coefficient related to the gate potential and has no unit. Here, since Vg0≈3.6 [V] and a temperature coefficient of Vth is approximately −1 [mV/deg], Kvg=277 [μ/deg].

Regarding a denominator of Expression (3), when a resistance value of the first resistor 28 at a temperature T0 is R0, a resistance value R of the first resistor 28 at a temperature T can be expressed by the following Expression (5).

$$\begin{matrix}[ Expression 5 ] & \\ R = {R}_{0} \{ 1 + ( T - {T}_{0} ) {K}_{R t} ) & ( 5 )\end{matrix}$$

In Expression (5), KRT is a temperature coefficient related to the resistance value and has no unit. At this time, KRT≈300 [μ/deg].

Further, when an overdrive voltage is Vovi, a replica current Iinv flowing through the second P-type MOS transistor 29 can be expressed by the following Expression (6).

$$\begin{matrix}[ Expression 6 ] & \\ Iinv = M \frac{β 1}{2} {( Vovi )}^{2} & ( 6 )\end{matrix}$$

Further, when an overdrive voltage at a temperature T0 is Vovi0, the following Expression (7) is satisfied for an overdrive voltage Vovi at a temperature T.

$$\begin{matrix}[ Expression 7 ] & \\ {Vovi}^{2} = {( {Vovi}_{0} ( 1 + ( {T}_{0} - T ) Kvovi ) )}^{2} & ( 7 )\end{matrix}$$

In Expression (7), Kvovi is a function of α. That is, a temperature coefficient of Vovi varies depending on a value a of α. Assuming that a=1/130, the coefficient Kvovi is about 130 [μ/deg]. Further, since 1 »(T0−T) Kvovi, the following Expression (8) is satisfied.

$$\begin{matrix}[ Expression 8 ] & \\ {Vovi}^{2} \approx {Vovio}^{2} ( 1 + ( {T}_{0} - T ) \cdot 2 Kovi ) & ( 8 )\end{matrix}$$

$$\begin{matrix}freq = \frac{Iinv}{2 CV g} = \frac{M \frac{{β}_{1}}{2} {( Vovi )}^{2}}{2 CV g} \\ \approx \frac{{M β}_{1} {Vovi 0}^{2}}{4 CV g 0} \cdot ( 1 + ( {T}_{0} - T ) \cdot ( 2 Kovi - Kvg ) )\end{matrix}$$

That is, α is designed such that 2Kvovi=Kvg. Here, 2Kvovi≈260 [μ/deg] and Kvg≈277 [μ/deg]. Accordingly, it can be understood that a temperature drift of the oscillation frequency f is reduced by insertion of the second resistor 52. Within a range of a temperature T=−40° C. to 170° C., the temperature drift of the oscillation frequency f is 1% or less.

According to the semiconductor device of the present embodiment having such a configuration, the following can be said. In the oscillation circuit 8A, the correction circuit 51 adjusts a first potential Vg1 that determines a current value of the replica current generated by the replica current generation circuit 21 by utilizing a temperature drift of the reference current Iref generated by the reference current generation circuit 20A. By adjustment of the first potential Vg1, a current value of the replica current Iinv can be made insensitive to temperature. That is, a slope of the replica current Iinv with respect to temperature can be made smaller, that is, made more gradual, in a temperature characteristic of the replica current Iinv. As a result, variation of a period of the ramp wave signal with respect to temperature can be reduced, and precision of the oscillation frequency f can be improved. As described above, it is possible to suppress the precision of the oscillation frequency f within ±5% in a usage temperature range from −40° C. to 170° C., which was an initial target.

It is to be noted that the oscillation circuit 8A is an example having the reference current generation circuit 20A in which the correction circuit 51 is inserted. The oscillation circuit 8B is an example having the reference current generation circuit 20B in which the second resistor 52 is inserted as the specific example of the correction circuit 51. Therefore, also in the semiconductor device including the oscillation circuit 8B, the same operation and effect as those of the semiconductor device including the oscillation circuit 8A can be naturally obtained.

In the above example, a case is assumed in which a resistance temperature coefficient of the first resistor 28 is positive and a temperature coefficient of the correction circuit 51 or the second resistor 52 is also positive. However, a case can also be assumed in which the resistance temperature coefficient of the first resistor 28 is negative and the temperature coefficient of the correction circuit 51 or the second resistor 52 is also negative. That is, it is sufficient that a sign of the resistance temperature coefficient of the first resistor 28 and a sign of the temperature coefficient of the correction circuit 51 or the second resistor 52 be the same.

### <First Pattern Layout Example on Semiconductor Substrate>

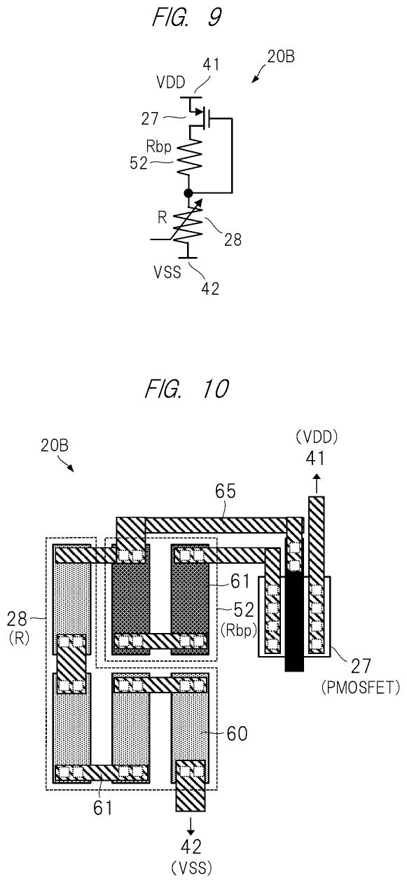

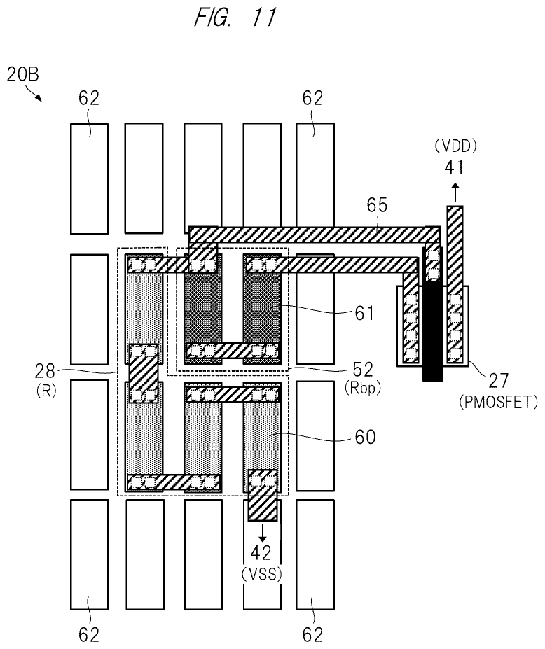

FIG. 9 is a circuit diagram of the reference current generation circuit 20B illustrated in FIG. 7. FIG. 10 is a diagram illustrating a first pattern layout example of the reference current generation circuit 20B on a semiconductor substrate.

The semiconductor device is configured such that a plurality of pattern elements, for example, transistor elements, resistor elements, capacitor elements, and the like, is arranged and formed on a semiconductor substrate, and these elements are connected by wirings. A material of the semiconductor substrate is, for example, silicon (Si), silicon carbide (SiC), gallium nitride (GaN), or the like.

Description will be made regarding the first pattern layout example of the reference current generation circuit 20B illustrated in FIG. 10. On the semiconductor substrate, a first P-type MOS transistor 27, one or a plurality of pattern elements 60 constituting a first resistor (R) 28, and one or a plurality of pattern elements 61 constituting a second resistor (Rbp) 52 are formed. When there is a plurality of the pattern elements 60 constituting the first resistor 28, the plurality of pattern elements 60 is connected to each other by a wiring 65 to constitute the first resistor 28. Similarly, when there is a plurality of the pattern elements 61 constituting the second resistor 52, each of the plurality of pattern elements 61 is connected to each other by the wiring 65 to constitute the second resistor 52.

A source of the first P-type MOS transistor 27 is connected to the wiring 65 connected to a high-potential power supply line 41 (VDD). A drain of the first P-type MOS transistor 27 and one end of the second resistor 52 are connected by the wiring 65. The other end of the second resistor 52 and one end of the first resistor 28 are connected by the wiring 65. A gate of the first P-type MOS transistor 27 is connected by the wiring 65 to a connection point between the second resistor 52 and the first resistor 28. An end of the first resistor 28 is connected to the wiring 65 connected to a low-potential power supply line 42 (VSS).

As illustrated in FIG. 10, in the first pattern layout example, the first P-type MOS transistor 27, a plurality of pattern elements 60 constituting the first resistor 28, and a plurality of pattern elements 61 constituting the second resistor 52 are arranged adjacent to each other. In this case, an area occupied by the first P-type MOS transistor 27, the first resistor 28, and the second resistor 52 is relatively small. Therefore, the first pattern layout example contributes to space saving on the semiconductor substrate.

### <Second Pattern Layout Example on Semiconductor Substrate>

FIG. 11 is a diagram illustrating a second pattern layout example of the reference current generation circuit 20B on the semiconductor substrate. As illustrated in FIG. 11, in the second pattern layout example, a plurality of pattern elements 60 constituting the first resistor (R) 28 and a plurality of pattern elements 61 constituting the second resistor (Rbp) 52 are arranged so as to be adjacent to each other. Further, a plurality of dummy elements 62, which are dummy pattern elements, is arranged adjacent to a region of a group of the plurality of pattern elements 60 and the plurality of pattern elements 61 and so as to surround the region. The dummy elements 62 are, in principle, pattern elements having no function such as resistance and usually not connected to the wiring 65. The dummy elements 62 are pattern elements having the same size and the same shape as other pattern elements. Further, the dummy elements 62, like other pattern elements, are arranged and formed at predetermined intervals, for example, in a matrix pattern.

In general, it is known that, when pattern elements formed on a semiconductor substrate have the same surrounding environment, relative forming precision thereof becomes better. For example, when another pattern element having the same size and shape is formed adjacent to a certain pattern element, the certain pattern element and the adjacent pattern element have better relative forming precision. Therefore, by forming pattern elements constituting a resistor so as to be adjacent to pattern elements constituting another resistor, relative precision of resistance values can be improved.

In the second pattern layout example illustrated in FIG. 11, dummy elements 62 are arranged adjacent to a region of groups of pattern elements constituting the first resistor 28 and the second resistor 52, in upward, downward, leftward, and rightward directions. That is, the dummy elements 62 are arranged on an outer periphery of the groups of pattern elements constituting the first resistor 28 and the second resistor 52. With such a configuration, a surrounding environment of the pattern elements 60 constituting the first resistor 28 and a surrounding environment of the pattern elements 61 constituting the second resistor 52 become the same. Accordingly, relative precision between a resistance value of the first resistor 28 and a resistance value of the second resistor 52 can be improved. In other words, a resistance ratio Rbp/R of the second resistor 52 to the first resistor 28 can be brought closer to a design target value. As a result, precision of the oscillation frequency f of the oscillation circuit 8B can be further improved.

### <Third Pattern Layout Example on Semiconductor Substrate>

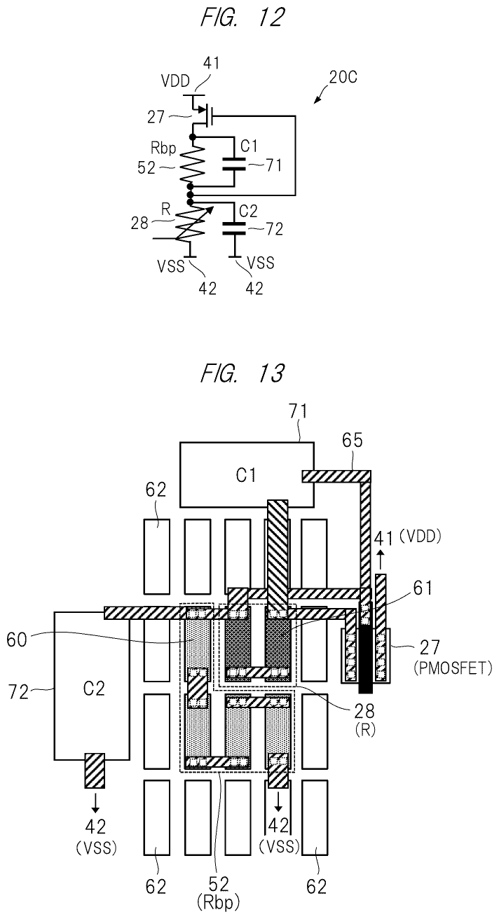

FIG. 12 is a circuit diagram of a reference current generation circuit 20C in the semiconductor device according to the present embodiment. FIG. 13 is a diagram illustrating a third pattern layout example of the reference current generation circuit 20C on the semiconductor substrate.

As illustrated in FIG. 12, the reference current generation circuit 20C has an additional filter capacitor as compared with the reference current generation circuit 20B. Specifically, in the reference current generation circuit 20C, a first filter capacitor 71 is connected in parallel with the second resistor 52 serving as the correction circuit 51, and a second filter capacitor 72 is connected in parallel with the first resistor 28. In the reference current generation circuit 20C, except for what is described above, the configuration thereof is the same as that of the reference current generation circuit 20B. By connecting the filter capacitors in parallel with the first resistor 28 and the second resistor 52, noise resistance is increased, and as a result, precision of the oscillation frequency f can be further improved.

In the pattern layout example of the reference current generation circuit 20C illustrated in FIG. 13, dummy elements 62 are arranged adjacent to a region of groups of pattern elements constituting the first resistor 28 and the second resistor 52 in upward, downward, leftward, and rightward directions. That is, the dummy elements 62 are arranged on an outer periphery of the groups of pattern elements constituting the first resistor 28 and the second resistor 52. Further, pattern elements corresponding to the first filter capacitor 71 and the second filter capacitor 72 are arranged adjacent to the dummy elements 62 on an outer side of the dummy elements 62. In the case of the reference current generation circuit 20C, as compared with the reference current generation circuit 20B, routing of the wiring 65 is partially different. However, a point is common that the dummy elements 62 are arranged on the outer periphery of the groups of pattern elements constituting the first resistor 28 and the second resistor 52.

With such a configuration, similarly to the case of the reference current generation circuit 20B, a surrounding environment of the pattern elements 60 constituting the first resistor 28 and a surrounding environment of the pattern elements 61 constituting the second resistor 52 become the same. Accordingly, relative precision between a resistance value of the first resistor 28 and a resistance value of the second resistor 52 can be improved. As a result, precision of the oscillation frequency f of can be further improved.

It is to be noted that the present inventor actually measured precision of the oscillation frequency using a large number of samples in the oscillation circuit 8B according to the present embodiment and the reference oscillation circuit 8. As a result, it was confirmed that the precision of the oscillation circuit 8B according to the present embodiment is improved by about two times or more as compared with the reference oscillation circuit 8.

When precision of the oscillation frequency in the oscillation circuit included in the semiconductor device is improved, there is also an advantage in a manufacturing process of the semiconductor device. In a general manufacturing process of a semiconductor device, in order to eliminate characteristic degradation at reflow, reflow is often performed after assembly. On the other hand, in the semiconductor device according to the present embodiment, even when characteristic degradation due to reflow and High Temperature Operating Life (HTOL) test is taken into consideration, it is possible to satisfy required precision. Therefore, frequency trimming can be performed at a wafer test stage. Accordingly, in the semiconductor device according to the present embodiment, contribution can be made to shortening of product shipment time and reduction of cost.

As described above, the invention made by the present inventor has been specifically described based on the embodiment. However, it goes without saying that the present invention is not limited to the above-described embodiment and can be variously modified without departing from the gist thereof.

For example, in the above embodiment, one replica current generation circuit is shared between the first ramp wave signal generation circuit and the second ramp wave signal generation circuit. However, two replica current generation circuits may be provided, and one may be used for each of the first ramp wave signal generation circuit and the second ramp wave signal generation circuit.

Further, for example, in the above embodiment, the semiconductor device according to the present embodiment is assumed to be for automotive use. However, the semiconductor device may be for other uses than automotive use. That is, the semiconductor device proposed herein can be applied to any case where a usage temperature range is relatively wide and high precision of an oscillation frequency of an oscillation circuit is required.

What is claimed is:

1. A semiconductor device comprising
an oscillation circuit,
wherein the oscillation circuit includes:
a reference current generation circuit including a first MOS transistor and a first resistor having a resistance temperature coefficient, where the reference current generation circuit is configured such that a reference current flows through the first MOS transistor and the first resistor;
a replica current generation circuit including a second MOS transistor through which a replica current of M times the reference current flows by application of a first potential, which is based on a gate potential of the first MOS transistor, to a gate of the second MOS transistor;
a first ramp wave signal generation circuit and a second ramp wave signal generation circuit, that alternately generate ramp wave signals based on charging and discharging of the replica current; and
a correction circuit that generates a voltage according to a current value of the reference current, and generates the first potential as a potential, which is shifted to a positive side, from the gate potential of the first MOS transistor by the generated voltage.

2. The semiconductor device according to claim 1, wherein the correction circuit is a second resistor arranged in a path through which the reference current flow.

3. The semiconductor device according to claim 2, wherein the second resistor has a resistance temperature coefficient whose sign is the same as a sign of the resistance temperature coefficient of the first resistor.

4. The semiconductor device according to claim 2,
wherein the first ramp wave signal generation circuit and the second ramp wave signal generation circuit each include a switch circuit arranged in a path through which the replica current flows and a capacitor that charges and discharges charges by the replica current through switching of the switch circuit, and generate a ramp wave signal based on a voltage of the capacitor.

5. The semiconductor device according to claim 4,
wherein the oscillation circuit further includes two comparators and a latch circuit,
wherein the ramp wave signal from the first ramp wave signal generation circuit and a reference potential are input to one of the two comparators,
wherein the ramp wave signal from the second ramp wave signal generation circuit and the reference potential are input to an other one of the two comparators, and
wherein an output of the one of the two comparators and an output of the other one of the two comparators are input to the latch circuit.

6. The semiconductor device according to claim 5,
wherein the first MOS transistor is a first P-type MOS transistor,
wherein the second MOS transistor is a second P-type MOS transistor,
wherein the switch circuit includes a switch P-type MOS transistor and a switch N-type MOS transistor,
wherein the reference current generation circuit is a circuit in which a source of the first P-type MOS transistor is connected to a high-potential power supply line, a drain of the first P-type MOS transistor is connected to one end of the second resistor, an other end of the second resistor is connected to one end of the first resistor, an other end of the first resistor is connected to a low-potential power supply line, and a gate of the first P-type MOS transistor is connected to the other end of the second resistor,
wherein the replica current generation circuit is a circuit in which a source of the second P-type MOS transistor is connected to the high-potential power supply line, and a gate of the second P-type MOS transistor is connected to the drain of the first P-type MOS transistor, and
wherein the first ramp wave signal generation circuit and the second ramp wave signal generation circuit are each a circuit in which a drain of the second P-type MOS transistor is connected to a source of the switch P-type MOS transistor, a drain of the switch P-type MOS transistor is connected to a drain of the switch N-type MOS transistor, a gate of the switch P-type MOS transistor and a gate of the switch N-type MOS transistor are connected to an output terminal of the latch circuit, source of the switch N-type MOS transistor is connected to the low-potential power supply line, the capacitor is connected between the source and the drain of the switch N-type MOS transistor, a connection point between the second resistor and the first resistor is connected to an inverting input terminal of one of the two comparators, and the drain of the switch N-type MOS transistor is connected to a non-inverting input terminal of the one comparator.

7. The semiconductor device according to claim 2,
wherein a resistance ratio of a resistance value of the second resistor to a resistance value of the first resistor is a value between 1/200 and 2/100.

8. The semiconductor device according to claim 1,
wherein the oscillation circuit includes a first filter capacitor connected in parallel with the correction circuit, and a second filter capacitor connected in parallel with the first resistor.

9. The semiconductor device according to claim 1,
wherein the semiconductor device is formed using a semiconductor substrate and a plurality of pattern elements arranged on the semiconductor substrate, and
wherein a plurality of dummy pattern elements is arranged adjacent to one or a plurality of pattern elements corresponding to the first resistor and a group of pattern elements including one or a plurality of pattern elements corresponding to the correction circuit, and is arranged so as to surround the group of pattern elements.

10. The semiconductor device according to claim 8,
wherein the semiconductor device is formed using a semiconductor substrate and a plurality of pattern elements arranged on the semiconductor substrate,
wherein a plurality of dummy pattern elements is arranged adjacent to one or a plurality of pattern elements corresponding to the first resistor and a group of pattern elements including one or a plurality of pattern elements corresponding to the correction circuit, and is arranged so as to surround the group of pattern elements, and
wherein pattern elements corresponding to the first filter capacitor and pattern elements corresponding to the second filter capacitor are arranged outside the plurality of dummy pattern elements.
